(19) United States
(12) Patent Application Publication
(10) Pub. No.: US 2024/0363531 A1
(43) Pub. Date: Oct. 31, 2024

(54) INTEGRATED CIRCUITS INCLUDING BACKSIDE WIRING

(71) Applicant: SAMSUNG ELECTRONICS CO., LTD., Suwon-si (KR)

(72) Inventors: Soyeon Kim, Suwon-si (KR); Hoyoung Tang, Suwon-si (KR); Taehyung Kim, Suwon-si (KR)

(21) Appl. No.: 18/626,935

(22) Filed: Apr. 4, 2024

(30) Foreign Application Priority Data
Apr. 26, 2023 (KR) 10-2023-0054976
Aug. 9, 2023 (KR) 10-2023-0104346

(51) Int. Cl. H01L 23/528; G11C 5/06; G11C 11/419; H01L 27/092; H01L 29/06; H01L 29/423; H01L 29/775; H01L 29/78; H01L 29/786; H10B 10/00

(52) U.S. Cl. CPC H01L 23/5283; G11C 5/063; G11C 11/419; H01L 27/0924; H01L 29/0673; H01L 29/42392; H01L 29/775; H01L 29/7851; H01L 29/78696; H10B 10/125

(57) ABSTRACT

Provided is an integrated circuit including a cell array disposed on a substrate and including a plurality of bit cells, a row decoder including a plurality of word line drivers each providing a plurality of word line signals to the cell array, a backside wiring layer disposed on a back side of the substrate to overlap the row decoder and providing power to the plurality of word line drivers, and a plurality of backside contacts between the row decoder and the backside wiring layer. Each of the plurality of backside contacts extends from a source of at least one transistor included in each of the plurality of word line drivers to the backside wiring layer.

### CROSS-REFERENCE TO RELATED APPLICATIONS

This application claims priority under 35 U.S.C. § 119 to Korean Patent Application Nos. 10-2023-0054976, filed on Apr. 26, 2023, and 10-2023-0104346, filed on Aug. 9, 2023 in the Korean Intellectual Property Office, the disclosures of which are incorporated by reference herein in their entireties.

### TECHNICAL FIELD

Aspects of this disclosure relate to integrated circuits, including integrated circuits having backside wiring.

### BACKGROUND

Due to demands for high integration and advancements in semiconductor processes, the width, spacing, and/or height of wires included in an integrated circuit may decrease and the influence of parasitic elements of wiring may increase. In addition, a power supply voltage of the integrated circuit may be reduced for reduced power consumption, high operating speed, etc., and accordingly, the influence of parasitic elements of wiring on the integrated circuit may be more significant.

### SUMMARY

Aspects of this disclosure provide an integrated circuit that uses a backside wiring layer to supply power to a word line driver, thereby improving performance and increasing routing resources in a frontside wiring layer, and a method of designing the same. Wires and vias can be efficiently routed to reduce the effects of parasitic elements, e.g., parasitic elements of wiring.

In some implementations, there is provided an integrated circuit including a cell array disposed on a substrate and including a plurality of bit cells, a row decoder including a plurality of word line drivers each providing a plurality of word line signals to the cell array, a backside wiring layer disposed on a back side of the substrate to overlap the row decoder and providing power to the plurality of word line drivers, and a plurality of backside contacts between the row decoder and the backside wiring layer, wherein each of the plurality of backside contacts extends from a source of at least one transistor included in each of the plurality of word line drivers to the backside wiring layer.

In some implementations, there is provided an integrated circuit including a cell array disposed on a substrate and including a plurality of bit cells, a plurality of word line drivers each providing a plurality of word line signals to the cell array, a frontside wiring layer disposed on the top of a front side of the substrate in a vertical direction and including a plurality of frontside wiring patterns that receive the plurality of word line signals, and a backside wiring layer disposed on a back side of the substrate to overlap the plurality of word line drivers and providing power to the plurality of word line drivers, wherein each of the plurality of word line drivers comprises a plurality of transistors, and each of the plurality of transistors comprises a source connected to the backside wiring layer.

In some implementations, there is provided an integrated circuit including a cell array including a plurality of bit cells, a plurality of word line drivers each providing a plurality of word line signals to the cell array, a frontside wiring layer disposed on the top of the plurality of word line drivers in a vertical direction and including a plurality of frontside wiring patterns that receive the plurality of word line signals, a backside wiring layer disposed on the bottom of the plurality of word line drivers in the vertical direction and including a first backside wiring pattern that provides a power supply voltage to the plurality of word line drivers and a second backside wiring pattern that provides a ground voltage to the plurality of word line drivers, a plurality of first backside contacts between the plurality of word line drivers and the first backside wiring pattern, and a plurality of second backside contacts between the plurality of word line drivers and the second backside wiring pattern.

### BRIEF DESCRIPTION OF DRAWINGS

Implementations will be more clearly understood from the following detailed description taken in conjunction with the accompanying drawings in which:

FIG. 1 is a layout of an integrated circuit according to some implementations;

FIG. 2 is a circuit diagram of an integrated circuit according to some implementations;

FIG. 3 is a cross-sectional view taken along line X1-X1′ of FIG. 1 according to some implementations;

FIG. 4 is a cross-sectional view taken along line X2-X2′ of FIG. 1 according to some implementations;

FIG. 5 is a cross-sectional view taken along line X3-X3′ of FIG. 1 according to some implementations;

FIG. 6 is a block diagram of a memory device included in an integrated circuit according to some implementations;

FIG. 7 is a circuit diagram of a cell array according to some implementations;

FIG. 8 is a plan view of a memory device according to some implementations;

FIG. 9 illustrates word line drivers included in a row decoder, according to some implementations;

FIG. 10 is a circuit diagram of a word line driver according to some implementations;

FIG. 11 is a plan view of a memory device according to some implementations;

FIG. 12 illustrates word line drivers included in a row decoder, according to some implementations;

FIGS. 13 to 18 are layouts of an integrated circuit, respectively, according to some implementations;

FIGS. 19A to 19D show elements according to some implementations;

FIG. 20 is a flowchart of a method of manufacturing an integrated circuit according to some implementations;

FIG. 21 is a block diagram of a system-on-chip according to some implementations; and

FIG. 22 is a block diagram of a computing system including memory for storing a program, according to some implementations.

### DETAILED DESCRIPTION

Hereinafter, some examples will be described in detail with reference to the attached drawings. The same reference numerals are used for the same components in the drawings, and duplicate descriptions thereof are omitted.

In this specification, an X-axis direction may be referred to as a first horizontal direction or a first direction, a Y-axis direction orthogonal to the X-axis may be referred to as a second horizontal direction or a second direction, and a Z-axis direction orthogonal to the X-axis and the Y-axis may be referred to as a vertical direction. A plane consisting of the X-axis and the Y-axis may be referred to as a horizontal plane, and a component placed in the +Z-axis direction relative to other components may be referred to as being above other components, while a component placed in the −Z-axis direction relative to other components may be referred to as being below other components.

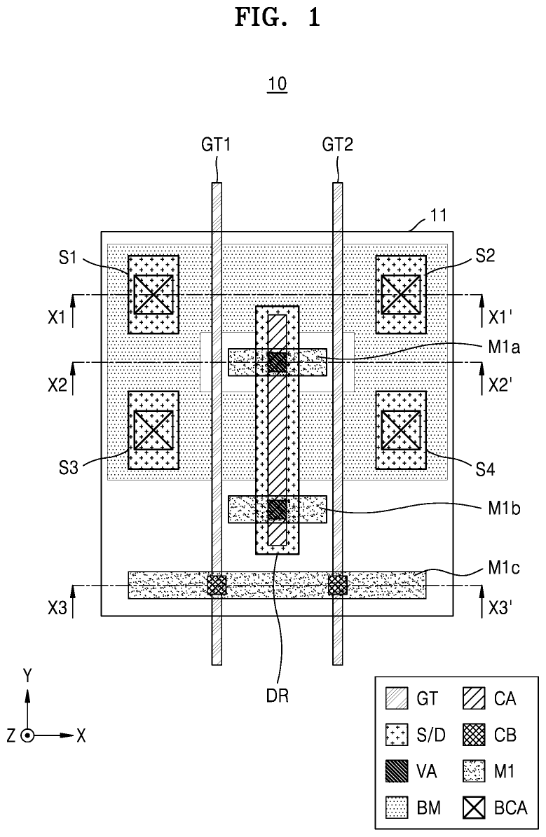

FIG. 1 is a layout of an integrated circuit 10 according to some implementations.

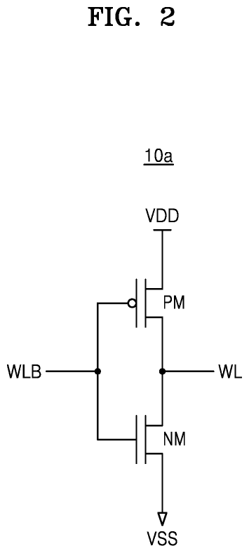

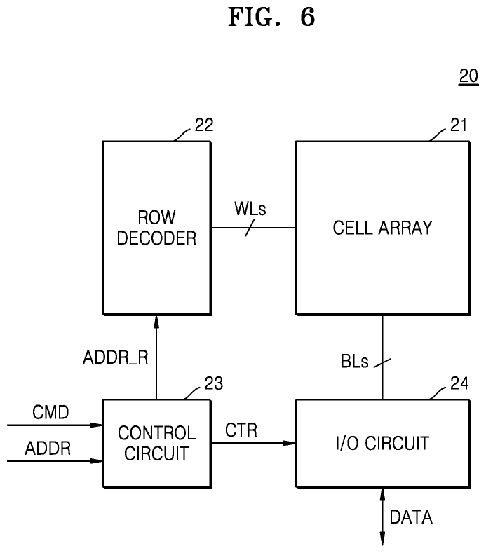

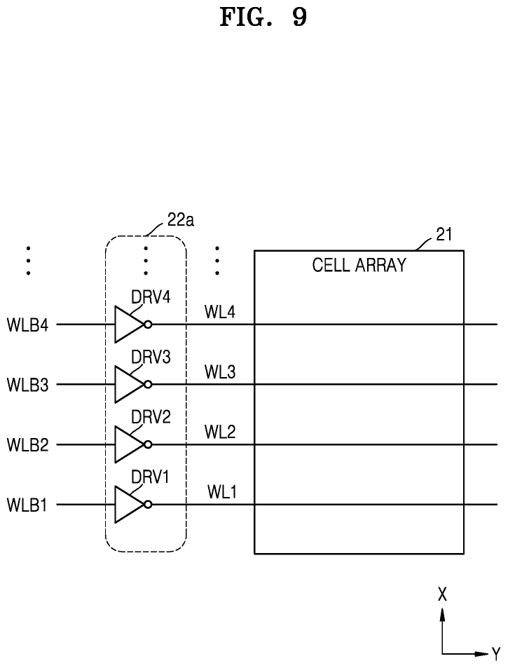

Referring to FIG. 1, the integrated circuit 10 may include an active region 11, source/drain regions S/D, gate lines GT, a first contact CA, second contacts CB, vias VA, a frontside wiring layer M1, a backside wiring layer BM, and backside contacts BCA. For example, the integrated circuit 10 may correspond to a row decoder (e.g., 22 in FIG. 6) included in a memory device. For example, the integrated circuit 10 may correspond to a word line driver (e.g., 22a in FIG. 9) included in the row decoder. For example, the integrated circuit 10 may correspond to a transistor (e.g., PM or NM in FIG. 2) included in the word line driver.

The integrated circuit 10 may be implemented as a semiconductor device, and a substrate on which the semiconductor device is formed may have a first side and a second side. For example, the first side may be a side on which circuit elements such as transistors are disposed, and the first side may be referred to herein as a “front side.” The second side may be a side opposite the first side, and the second side may be referred to herein as a “back side.”

The active region 11 may be disposed on the front side of the substrate and may be of a first conductivity type. Depending on the implementation, the active region 11 may be referred to as a substrate or a transistor region. For example, the active region 11 may be a diffusion region doped with impurities that change the electrical properties of the substrate material. The source/drain regions S/D may be disposed on the active region 11. For example, the source/drain regions S/D may include an epitaxial region of a semiconductor material such as silicon, boron, phosphorus, germanium, carbon, SiGe, and/or SiC. For example, the source/drain regions S/D may have a different type of doping material than that of the active region 11. In some implementations, the source/drain regions S/D may include first to fourth source regions S1 to S4 and a drain region DR.

The gate lines GT may include first and second gate lines GT1 and GT2, which each extend in the second direction Y and are spaced apart from each other in the first direction X. The gate lines GT may be defined as conductive segments including a conductive material such as polysilicon, and one or more metals. The first contact CA may be disposed on the drain region DR and may extend in the second direction Y. Accordingly, the first contact CA may be referred to as a “drain contact.” The second contacts CB may be disposed on the first and second gate lines GT1 and GT2 and connected to the first and second gate lines GT1 and GT2, respectively. Accordingly, the second contacts CB may be referred to as “gate contacts.”

The active region 11, the source/drain regions S/D, and gate lines GT may constitute a transistor, for example, a PMOS transistor PM or an NMOS transistor NM in FIG. 2. The substrate on which the active region 11, the source/drain regions S/D, the gate lines GT, the first contact CA, and the second contacts CB are placed may be referred to as a device layer.

In some implementations, the integrated circuit 10 may include the frontside wiring layer M1 and the backside wiring layer BM, and may implement a power distribution network using the frontside wiring layer M1 and the backside wiring layer BM. Accordingly, some of signals and/or powers applied to the source/drain regions S/D and/or the gate lines GT may be transferred through the frontside wiring layer M1, and others thereof may be transferred through the backside wiring layer BM. Therefore, according to some implementations, the performance of the integrated circuit 10 may be improved by reducing IR drop since it is possible to greatly reduce the complexity of routing and the length of at least some wires and/or vias, compared to a structure in which wires are placed only on the front side of the substrate (e.g., without the backside wiring layer BM). The “IR drop” is the voltage drop due to resistance in wires and vias.

In some implementations, the frontside wiring layer M1 may be used as signal wiring to transfer signals to the integrated circuit 10, and the backside wiring layer BM may be used as power wiring to transfer power to the integrated circuit 10. Specifically, the frontside wiring layer M1 may transfer an input signal (e.g., a complementary word line signal WLB in FIG. 2) and an output signal (e.g., a word line signal WL in FIG. 2) to the integrated circuit 10. In addition, the backside wiring layer BM may provide power, such as a positive supply voltage (e.g., power supply voltage VDD in FIG. 2) or a negative supply voltage (e.g., ground voltage VSS in FIG. 2), to the integrated circuit 10.

The frontside wiring layer M1 may be placed on the top of the device layer in a vertical direction Z, and the backside wiring layer BM may be positioned on the bottom of the device layer in the vertical direction Z. The frontside wiring layer M1 may include first to third frontside wiring patterns M1a, M1b, and M1c, each extending in the first direction X and spaced apart from each other in the second direction Y. The third frontside wiring pattern M1c may correspond to an input node or an input terminal of the integrated circuit 10 and may receive an input signal, for example, a complementary word line signal (WLB in FIG. 2). The first and second frontside wiring patterns M1a and M1b may correspond to an output node or an output terminal of the integrated circuit 10 and may receive an output signal, for example, a word line signal (WL in FIG. 2).

FIG. 2 is a circuit diagram of an integrated circuit 10a according to some implementations.

Referring to FIG. 2, the integrated circuit 10a may correspond to a word line driver. For example, the integrated circuit 10a may include a P-type transistor, such as a PMOS transistor PM, and an N-type transistor, such as an NMOS transistor NM, where the PMOS transistor PM and the NMOS transistor NM may be connected in series with each other. The PMOS transistor PM may include a source that receives the power supply voltage VDD, a gate that receives the complementary word line signal WLB, and a drain that outputs the word line signal WL. The NMOS transistor NM may include a source that receives the ground voltage VSS, a gate that receives the complementary word line signal WLB, and a drain that outputs the word line signal WL.

In some implementations, the PMOS transistor PM and/or the NMOS transistor NM may be implemented as a multi-finger transistor. The finger may correspond to a gate of a transistor. To reduce a resistance component of the gate, a single-finger transistor having one gate may be divided into a plurality of transistors having a plurality of gates, thereby implementing the single-finger transistor as a multi-finger transistor.

In some implementations, the PMOS transistor PM may be implemented as a multi-finger transistor, and the multi-finger transistor may be implemented as, for example, the integrated circuit 10 of FIG. 1. The power supply voltage VDD may be applied to the backside wiring layer BM. The backside wiring layer BM may be connected to the source of the PMOS transistor PM, for example, the first to fourth source regions S1 to S4, through the backside contacts BCA and may transfer the power supply voltage VDD to the first to fourth source regions S1 to S4. The third frontside wiring pattern M1c may be connected to the first and second gate lines GT1 and GT2 through the second contacts CB and may transfer the complementary word line signal WLB to the first and second gate lines GT1 and GT2. The first and second frontside wiring patterns M1a and M1b may be connected to the drain of the PMOS transistor PM, for example, the drain region DR, through the first contact CA and may receive the word line signal WL from the drain region DR.

In some implementations, the NMOS transistor NM may be implemented as a multi-finger transistor, and the multi-finger transistor may be implemented as, for example, the integrated circuit 10 of FIG. 1. The ground voltage VSS may be applied to the backside wiring layer BM. The backside wiring layer BM may be connected to the source of the NMOS transistor NM, for example, the first to fourth source regions S1 to S4, through the backside contacts BCA and may transfer the ground voltage VSS to the first to fourth source regions S1 to S4. The third frontside wiring pattern M1c may be connected to the first and second gate lines GT1 and GT2 through the second contacts CB and may transfer the complementary word line signal WLB to the first and second gate lines GT1 and GT2. The first and second frontside wiring patterns M1a and M1b may be connected to the drain of the NMOS transistor NM, for example, the drain region DR, through the first contact CA and may receive the word line signal WL from the drain region DR.

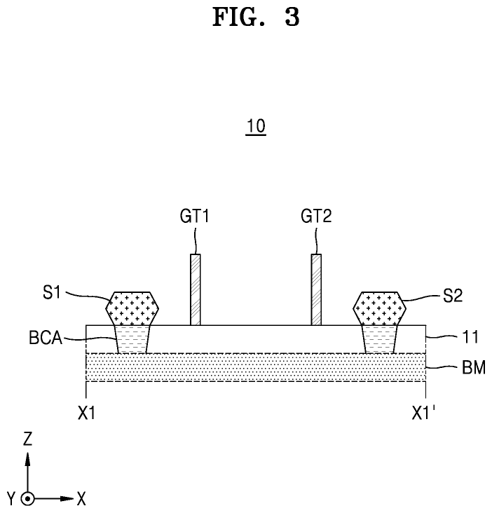

FIG. 3 is a cross-sectional view taken along line X1-X1′ of FIG. 1 according to some implementations.

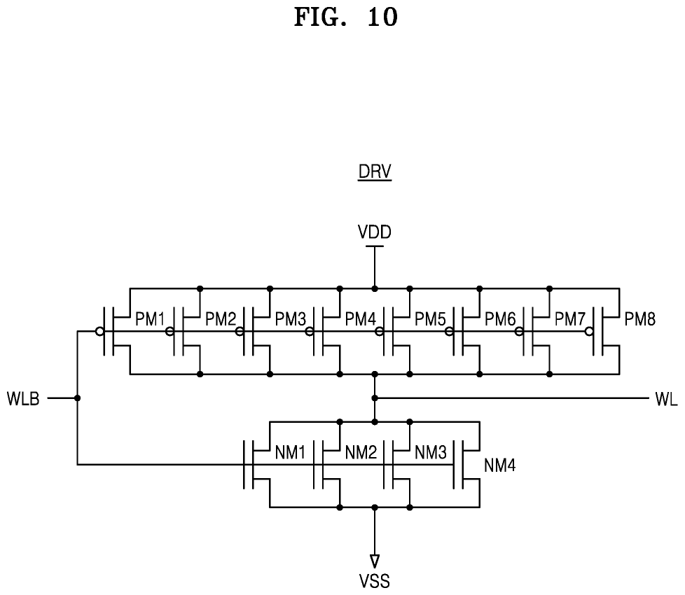

Referring to FIGS. 1 and 3 together, the first and second source regions S1 and S2 may be placed on the active region 11. The first source region S1 and the first gate line GT1 may be included in a first transistor (e.g., PM1 in FIG. 10), and the second source region S2 and the second gate line GT2 may be included in a second transistor (e.g., PM2 in FIG. 10). The same voltage (e.g., WLB in FIG. 10) may be applied to the first and second gate lines GT1 and GT2, and the first and second transistors may form a multi-finger transistor.

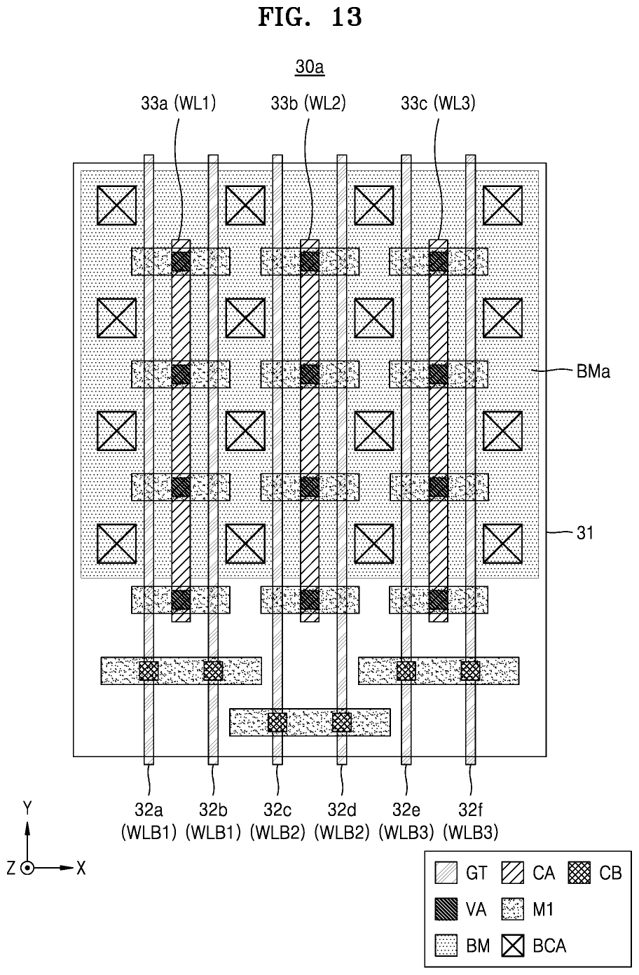

The backside wiring layer BM may be disposed on the back side of the substrate and may be connected to elements in the substrate, such as diffusion regions, through the backside contacts BCA. In some implementations, the backside wiring layer BM may overlap the row decoder included in the memory device in the vertical direction Z. In some implementations, the backside wiring layer BM may overlap the word line driver included in the row decoder in the vertical direction Z. In some implementations, the backside wiring layer BM may overlap the transistor included in the word line driver in the vertical direction Z. For example, the backside wiring layer BM may include a mesh-type backside wiring pattern. However, implementations according to this disclosure are not limited thereto, and the arrangement and/or extension direction of the backside wiring layer BM may vary depending on the implementation, as shown in FIGS. 13 to 18.

The backside contacts BCA may be placed between the backside wiring layer BM and the first to fourth source regions S1 to S4, and the backside wiring layer BM may be connected to the first to fourth source regions S1 to S4 through the backside contacts BCA. Accordingly, the backside contacts BCA may be referred to as “source contacts” or “backside source contacts.” For example, each of the backside contacts BCA may extend from the source of at least one transistor included in the word line driver, for example, the first to fourth source regions S1 to S4, to the backside wiring layer BM. In some implementations, a lower surface of each of the backside contacts BCA may be in contact with an upper surface of the backside wiring layer BM, and an upper surface of each of the backside contacts BCA may contact a lower surface of each of the first to fourth source regions S1 to S4.

A structure that connects a contact to a lower part of the epitaxial region, such as the source/drain region S/D, may be referred to as a “direct backside contact (DBC).” In some implementations, the DBC may include backside contacts and/or backside vias. In some implementations, additional backside vias may be placed between the backside wiring layer BM and the backside contacts BCA, or between the backside contacts BCA and the source/drain regions S/D.

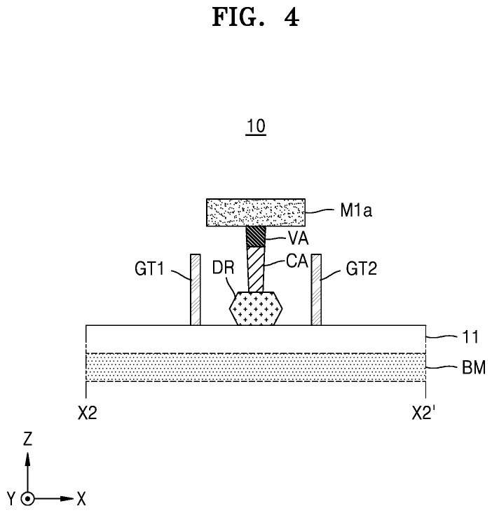

FIG. 4 is a cross-sectional view taken along line X2-X2′ of FIG. 1 according to some implementations.

Referring to FIG. 1 and FIG. 4 together, the drain region DR may be placed on the active region 11. The drain region DR may be placed between the first and second gate lines GT1 and GT2. For example, the drain region DR may extend in the second direction Y. The first contact CA may be disposed on the drain region DR, the via VA may be disposed on the first contact CA, and the first frontside wiring pattern M1a may be disposed on the via VA. As such, the drain region DR may be connected to the first frontside wiring pattern M1a through the first contact CA and the via VA and may transfer an output signal, for example, a word line signal (e.g., WL in FIG. 2), to the first frontside wiring pattern M1a.

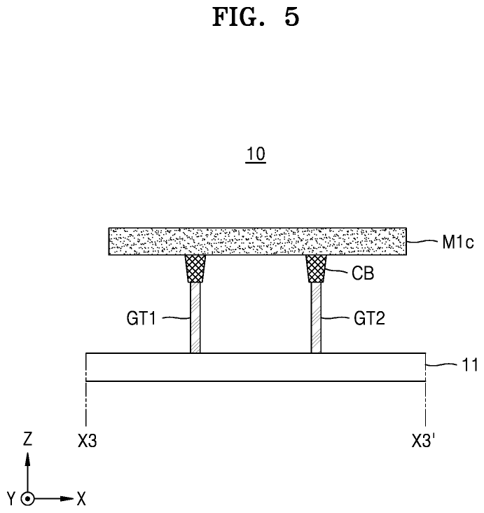

FIG. 5 is a cross-sectional view taken along line X3-X3′ of FIG. 1 according to some implementations.

Referring to FIG. 1 and FIG. 5 together, the first and second gate lines GT1 and GT2 may be disposed on the active region 11. For example, the first and second gate lines GT1 and GT2 may each extend in the second direction Y. The second contacts CB may be disposed on the first and second gate lines GT1 and GT2, respectively, and the third frontside wiring pattern M1c extending in the first direction X may be disposed on the second contacts CB. As such, the first and second gate lines GT1 and GT2 may be connected to the third frontside wiring pattern M1c through the second contacts CB and may receive an input signal, for example, a complementary word line signal (e.g., WLB in FIG. 2), from the third frontside wiring pattern M1c.

FIG. 6 is a block diagram of a memory device 20 included in an integrated circuit according to some implementations.

Referring to FIG. 6, the memory device 20 includes a cell array 21, a row decoder 22, a control circuit 23, and an input/output (I/O) circuit 24. The row decoder 22, the control circuit 23, and the I/O circuit 24 may be collectively referred to as a peripheral circuit. In some implementations, the peripheral circuit may further include a command buffer, an address buffer, and/or a voltage generator. For example, the memory device 20 may be implemented as or including the integrated circuit 10 of FIG. 1.

The memory device 20 may receive a command CMD, an address ADDR, and data DATA. For example, the memory device 20 may receive the command CMD, the address ADDR, and the data DATA, the command CMD instructing to perform a write operation, and may store the received data DATA in a region of the cell array 21 corresponding to the address ADDR. In addition, the memory device 20 may receive the command CMD and the address ADDR, the command CMD instructing to perform a read operation, and may output the data DATA stored in the region of the cell array 21 corresponding to the address ADDR to the outside.

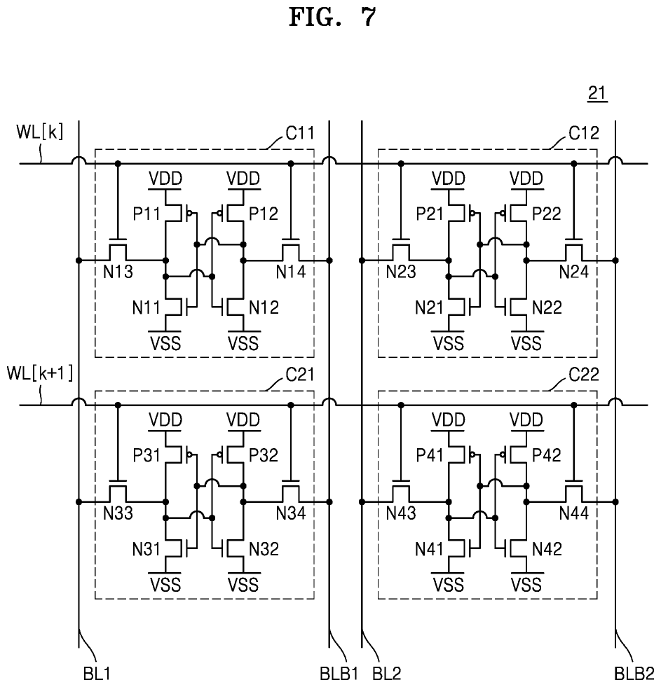

The cell array 21 may include a plurality of bit cells or memory cells accessed by a plurality of word lines WLs and a plurality of bit lines BLs. In some implementations, the memory cells included in the cell array 21 may be volatile memory cells, such as static random access memory (SRAM) cells, dynamic random access memory (DRAM) cells, etc. In some implementations, the memory cells included in the cell array 21 may be non-volatile memory cells, such as flash memory cells, resistive random access memory (RRAM) cells, etc. Some implementations are described primarily with reference to SRAM cells, as described below with reference to FIG. 7, but the scope of this disclosure is not limited thereto.

The control circuit 23 may generate a row address ADDR_R and a control signal CTR based on the command CMD and the address ADDR. For example, the control circuit 23 may identify a read command by decoding the command CMD and may generate the row address ADDR_R and the control signal CTR to read the data DATA from the cell array 21. In addition, the control circuit 23 may identify a write command by decoding the command CMD and may generate the row address ADDR_R and the control signal CTR to write the data DATA into the cell array 21.

The row decoder 22 may be connected to the cell array 21 through the plurality of word lines WLs and may activate one word line among the plurality of word lines WLs according to the row address ADDR_R. Accordingly, among the memory cells included in the cell array 21, memory cells connected to the activated word line may be selected. The row decoder 22 may include a row driver. In some implementations, the row decoder 22 may be understood to include the row driver.

The I/O circuit 24 may be connected to the cell array 21 through the plurality of bit lines BLs and may perform a read operation or a write operation according to the control signal CTR. For example, the I/O circuit 24 may include a column driver. The column driver may detect the current and/or voltage in the plurality of bit lines BLs or may apply the current and/or voltage to the plurality of bit lines BLs at a timing determined based on the control signal CTR.

FIG. 7 is a circuit diagram of a cell array 21 according to some implementations.

Referring to FIG. 7, the cell array 21 may include memory cells C11, C12, C21, and C22 arranged adjacent to each other. For example, the cell array 21 of FIG. 7 may correspond to an example of the cell array 21 in FIG. 6. The memory cells C11 and C12 arranged in the same row may be commonly connected to a word line WL[k], and the memory cells C21 and C22 arranged in the same row may be commonly connected to a word line WL[k+1], where k is an integer greater than 0. In addition, the memory cells C11 and C21 arranged in the same column may be connected to a first bit line BL1 and a first complementary bit line BLB1, and the memory cells C12 and C22 arranged in the same column may be connected to a second bit line BL2 and a second complementary bit line BLB2.

The memory cell C11 may include a first PFET P11, a second PFET P12, and first to fourth NFETs N11 to N14, and may be a 6T (six transistors) SRAM cell. The memory cell C11 may include a cross-coupled inverter pair between a node to which the positive supply voltage (or cell voltage) VDD is applied and a node to which the negative supply voltage (or ground voltage) VSS is applied. For example, a first inverter of the cross-coupled inverter pair may include the first PFET P11 and the first NFET N11, and a second inverter of the cross-coupled inverter pair may include the second PFET P12 and the second NFET N12. In addition, the third NFET N13 and the fourth NFET N14 may be referred to as transfer transistors or pass transistors configured to connect the first inverter and the second inverter to the first bit line BL1 and the first complementary bit line BLB1, respectively, through the activated (e.g., with a high-level voltage) word line WL[k]. As shown in FIG. 6, the memory cells C12, C21, and C22 may have the same structure corresponding to the memory cell C11, and thus, the description of the memory cell C11 may be applied to the memory cells C12, C21, and C22.

The memory cell C12 may include a first PFET P21, a second PFET P22, and first to fourth NFETs N21 to N24. The third NFET N23 and the fourth NFET N24 may be configured to connect a first inverter including the first PFET P21 and the first NFET N21 and a second inverter including the second PFET P22 and the second NFET N22 to the second bit line BL2 and the second complementary bit line BLB2, respectively, through the activated word line WL[k].

The memory cell C21 may include a first PFET P31, a second PFET P32, and first to fourth NFETs N31 to N34. The third NFET N33 and the fourth NFET N34 may be configured to connect a first inverter including the first PFET P31 and the first NFET N31 and a second inverter including the second PFET P32 and the second NFET N32 to the first bit line BL1 and the first complementary bit line BLB1, respectively, through the activated word line WL[k+1].

The memory cell C22 may include a first PFET P41, a second PFET P42, and first to fourth NFETs N41 to N44. The third NFET N43 and the fourth NFET N44 may be configured to connect a first inverter including the first PFET P41 and the first NFET N41 and a second inverter including the second PFET P42 and the second NFET N42 to the second bit line BL2 and the second complementary bit line BLB2, respectively, by the activated word line WL[k+1].

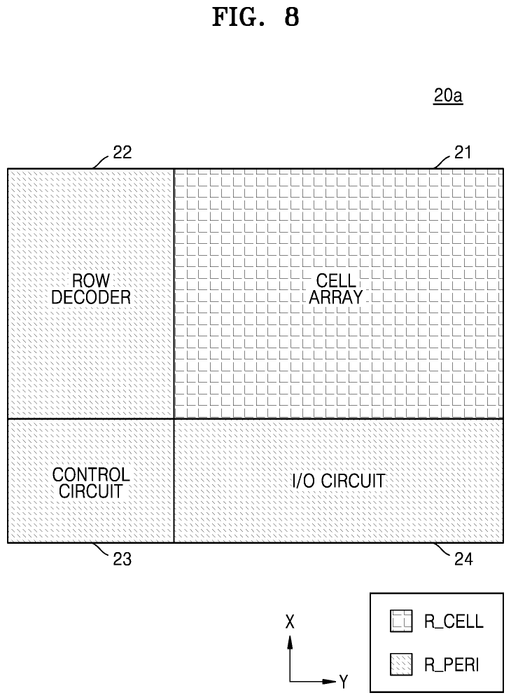

FIG. 8 is a plan view of a memory device 20a according to some implementations.

Referring to FIG. 8, the memory device 20a may include at least one cell array placed in a cell array region R_CELL and may include a peripheral circuit placed in a peripheral region R_PERI. For example, the memory device 20a may represent an example of a layout of an integrated circuit corresponding to the memory device 20 of FIG. 6. For example, the cell array 21 may be placed in the cell array region R_CELL, and the row decoder 22, the control circuit 23, and the I/O circuit 24 may be placed in the peripheral region R_PERI.

The row decoder 22 may be placed adjacent to the cell array 21 in the second direction Y. However, the row decoder 22 is not limited thereto, and the row decoder 22 may be placed adjacent to the cell array 21 in the first direction X. In some implementations, signal wires connected to the row decoder 22 may be implemented as the frontside wiring layer (e.g., M1 in FIG. 1) disposed above the front side of the substrate, and power wires connected to the row decoder 22 may be implemented as the backside wiring layer (e.g., BM in FIG. 1) disposed on the back side of the substrate. For example, the backside wiring layer connected to the row decoder 22 may overlap with the row decoder 22 in the vertical direction (e.g., be at least partially under the row decoder 22).

FIG. 9 illustrates word line drivers 22a included in a row decoder, according to some implementations.

Referring to FIG. 9, the row decoder (e.g., 22 in FIG. 8) may include the word line drivers 22a, and the word line drivers 22a may be connected to the cell array 21 through a plurality of word lines. For example, the word line drivers 22a may include first to fourth word line drivers DRV1 to DRV4. The first word line driver DRV1 may receive a first complementary word line signal WLB1 and provide a first word line signal WL1. The second word line driver DRV2 may receive a second complementary word line signal WLB2 and provide a second word line signal WL2. The third word line driver DRV3 may receive a third complementary word line signal WLB3 and provide a third word line signal WL3. The fourth word line driver DRV4 may receive a fourth complementary word line signal WLB4 and provide a fourth word line signal WL4.

FIG. 10 is a circuit diagram of a word line driver DRV according to some implementations.

Referring to FIG. 10, the word line driver DRV may include a plurality of P-type transistors, for example, a plurality of PMOS transistors PM1 to PM8, and a plurality of N-type transistors, for example, a plurality of NMOS transistors NM1 to NM4. The number of PMOS transistors (e.g., PM1 to PM8) and the number of NMOS transistors (e.g., NM1 to NM4) may vary depending on the implementation. For example, the word line driver DRV may correspond to one of the first to fourth word line drivers DRV1 to DRV4 of FIG. 9.

For example, the PMOS transistor PM of FIG. 2 may be implemented as a multi-finger transistor including the plurality of PMOS transistors PM1 to PM8. For example, the NMOS transistor NM in FIG. 2 may be implemented as a multi-finger transistor including the plurality of NMOS transistors NM1 to NM4. The descriptions given above with reference to FIG. 2 may also be applied to this example.

Each of the plurality of PMOS transistors PM1 to PM8 may include a source that receives a positive supply voltage (e.g., power supply voltage VDD), a gate that receives a complementary word line signal WLB, and a drain that provides a word line signal WL. Each of the plurality of NMOS transistors NM1 to NM4 may include a source that receives a negative supply voltage (e.g., ground voltage VSS), a gate that receives a complementary word line signal WLB, and a drain that provides a word line signal WL.

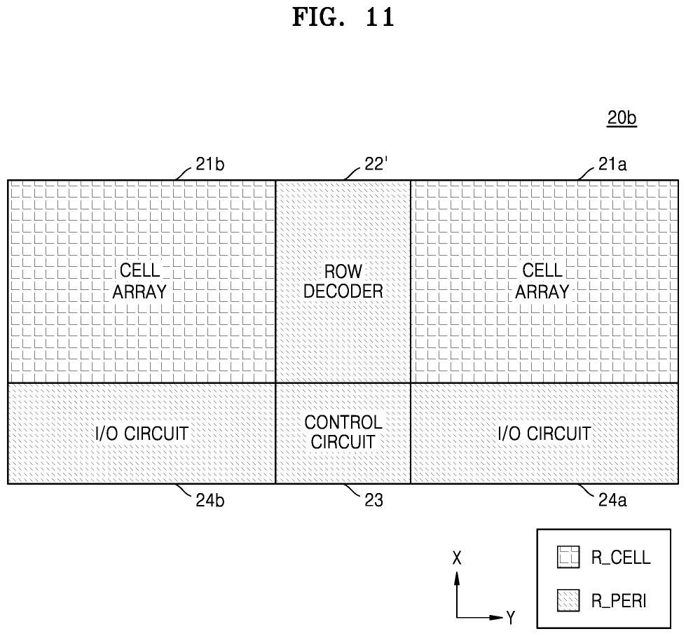

FIG. 11 is a plan view of a memory device 20b according to some implementations.

Referring to FIG. 11, the memory device 20b may include at least one cell array placed in a cell array region R_CELL and may include a peripheral circuit placed in a peripheral region R_PERI. For example, the memory device 20b may represent an example of a layout of an integrated circuit corresponding to the memory device 20 of FIG. 6. For example, first and second cell arrays 21a and 21b may be placed in the cell array region R_CELL, and a row decoder 22′, a control circuit 23, and first and second I/O circuits 24a and 24b may be placed in the peripheral region R_PERI.

The row decoder 22′ may be placed between the first and second cell arrays 21a and 21b. In some implementations, signal wires connected to the row decoder 22′ may be implemented as a frontside wiring layer (e.g., M1 in FIG. 1) disposed on the top of the front side of the substrate, and power wires connected to the row decoder 22′ may be implemented as a backside wiring layer (e.g., BM in FIG. 1) disposed on the back side of the substrate. For example, the backside wiring layer connected to the row decoder 22′ may overlap with the row decoder 22′ in the vertical direction (e.g., be at least partially under the row decoder 22′).

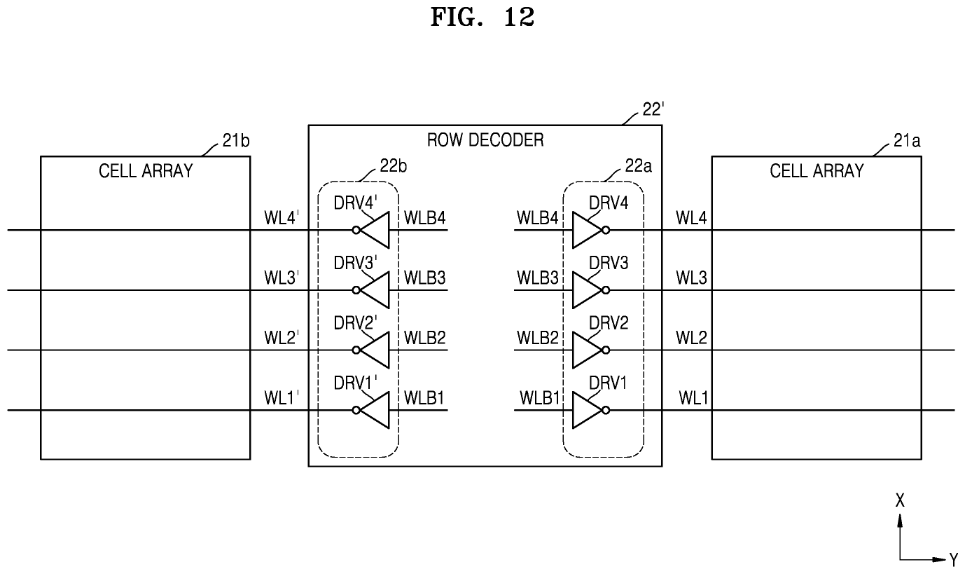

FIG. 12 illustrates word line drivers 22a and 22b included in a row decoder, according to some implementations.

Referring to FIG. 12, the row decoder (e.g., 22′ in FIG. 11) may include the word line drivers 22a and 22b, where the word line drivers 22a may be connected to the first cell array 21a through the plurality of word lines, and the word line drivers 22b may be connected to the second cell array 21b through the plurality of word lines.

For example, the word line drivers 22a may include first to fourth word line drivers DRV1 to DRV4. The first word line driver DRV1 may receive a first complementary word line signal WLB1 and provide a first word line signal WL1. The second word line driver DRV2 may receive a second complementary word line signal WLB2 and provide a second word line signal WL2. The third word line driver DRV3 may receive a third complementary word line signal WLB3 and provide a third word line signal WL3. The fourth word line driver DRV4 may receive a fourth complementary word line signal WLB4 and provide a fourth word line signal WL4.

For example, the word line drivers 22b may include first to fourth word line drivers DRV1′ to DRV4′. The first word line driver DRV1′ may receive a first complementary word line signal WLB1 and provide a first word line signal WL1′. The second word line driver DRV2′ may receive a second complementary word line signal WLB2 and provide a second word line signal WL2′. The third word line driver DRV3′ may receive a third complementary word line signal WLB3 and provide a third word line signal WL3′. The fourth word line driver DRV4′ may receive a fourth complementary word line signal WLB4 and provide a fourth word line signal WL4′.

FIG. 13 is a layout of an integrated circuit 30a according to some implementations.

Referring to 13, the integrated circuit 30a may include gate lines GT, first contacts CA, second contacts CB, vias VA, a frontside wiring layer M1, a backside wiring layer BM, and backside contacts BCA. In some implementations, the integrated circuit 30a may correspond to some regions of the first to third word line drivers DRV1, DRV2, and DRV3 of FIG. 9. For example, the integrated circuit 30a may correspond to the PMOS transistor region of the first to third word line drivers DRV1, DRV2, and DRV3. In some implementations, the integrated circuit 30a may correspond to some regions of the first to third word line drivers DRV1, DRV2, and DRV3 of FIG. 11 or some regions of the first to third word line drivers DRV1′, DRV2′, and DRV3′. For example, the integrated circuit 30a may correspond to the PMOS transistor region of the first to third word line drivers DRV1′, DRV2′, and DRV3′. The descriptions given above with reference to FIGS. 1 to 12 may also be applied to this example.

The gate lines GT may include gate lines 32a to 32f each extending in the second direction Y on the substrate or the active region 31. The second contacts CB may be disposed on the gate lines 32a to 32f, respectively, and each of the gate lines 32a to 32f may receive an input signal, for example, a complementary word line signal, from the frontside wiring layer M1 through the corresponding second contact CB.

The same input signal may be applied to a pair of adjacent gate lines GT. For example, the first complementary word line signal WLB1 may be applied to the gate lines 32a and 32b, the second complementary word line signal WLB2 may be applied to the gate lines 32c and 32d, and the third complementary word line signal WLB3 may be applied to the gate lines 32e and 32f.

The first contacts CA may be respectively disposed on a plurality of drain regions. The vias VA may be disposed on the first contacts CA, respectively, and each of the plurality of drain regions may be connected to the frontside wiring layer M1 through the corresponding first contact CA and the corresponding via VA. For example, the first contacts CA may include first contacts 33a, 33b, and 33c, each extending in the second direction Y on the substrate or the active region 31.

Each of the first contacts 33a, 33b, and 33c may be placed between a pair of gate lines GT to which the same input signal is applied. For example, the first contact 33a may be disposed on the drain region between the gate lines 32a and 32b to which the first complementary word line signal WLB1 is applied, and the first word line signal WL1 may be output through the first contact 33a. For example, the first contact 33b may be disposed on the drain region between the gate lines 32c and 32d to which the second complementary word line signal WLB2 is applied, and the second word line signal WL2 may be output through the first contact 33b. For example, the first contact 33c may be disposed on the drain region between the gate lines 32e and 32f to which the third complementary word line signal WLB3 is applied, and the third word line signal WL3 may be output through the first contact 33c.

The backside wiring layer BM may include a backside wiring pattern BMa disposed under the substrate or the active region 31 to overlap the first to third word line drivers DRV1, DRV2, and DRV3 in the vertical direction Z. An area of the backside wiring pattern BMa may correspond to the size of the first to third word line drivers DRV1, DRV2, and DRV3. For example, the backside wiring pattern BMa may be implemented as a wide pattern corresponding to the size of the transistor included in the first to third word line drivers DRV1, DRV2, and DRV3 or the number of fingers of the multi-finger transistor. Accordingly, IR drop may be reduced by increasing power capacitance and reducing resistance.

For example, the area of the backside wiring pattern BMa may correspond to the number or size of transistors included in each of the first to third word line drivers DRV1, DRV2, and DRV3. For example, as the number of P-type transistors included in each of the first to third word line drivers DRV1, DRV2, and DRV3 increases, the area of the backside wiring pattern BMa may increase. For example, as the number of N-type transistors included in each of the first to third word line drivers DRV1, DRV2, and DRV3 increases, the area of the backside wiring pattern BMa may increase.

The backside contacts BCA may be placed between the backside wiring pattern BMa and the plurality of source regions. The backside contacts BCA may be disposed on the backside wiring pattern BMa and may extend in the vertical direction Z to penetrate the substrate or the active region 31. Each of the backside contacts BCA may extend from the source of at least one transistor included in the word line driver to the backside wiring pattern BMa. For example, the backside contacts BCA may be respectively connected to source regions of transistors included in the first to third word line drivers DRV1, DRV2, and DRV3.

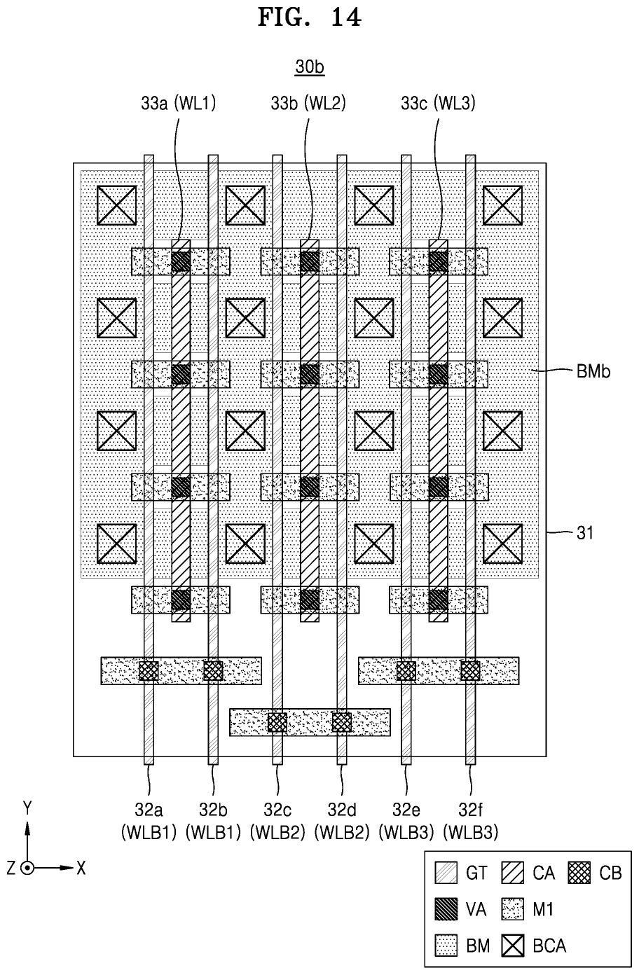

FIG. 14 is a layout of an integrated circuit 30b according to some implementations.

Referring to FIG. 14, the integrated circuit 30b may correspond to a modified example of the integrated circuit 30a of FIG. 13, and the descriptions given above with reference to FIG. 13 may also be applied to this example. The integrated circuit 30b may include a backside wiring pattern BMb implemented as a mesh type. For example, the backside wiring pattern BMb may include first backside wiring patterns extending in the first direction X and second backside wiring patterns extending in the second direction Y, where the first and second backside wiring patterns may be arranged in a mesh pattern.

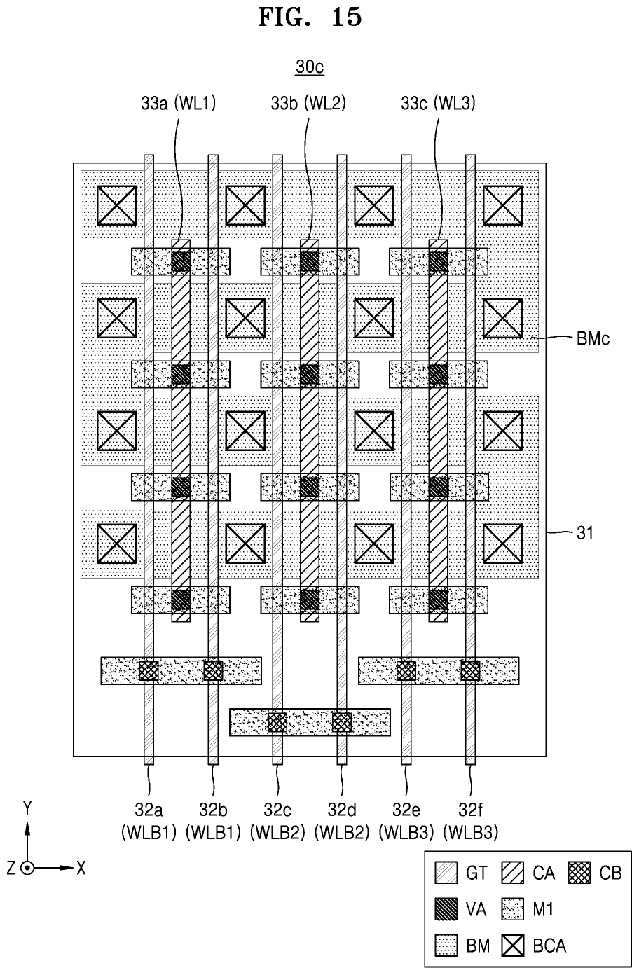

FIG. 15 is a layout of an integrated circuit 30c according to some implementations.

Referring to FIG. 15, the integrated circuit 30c may correspond to a modified example of the integrated circuit 30a of FIG. 13, and the descriptions given above with reference to FIG. 13 may also be applied to this example. The integrated circuit 30c may include a backside wiring pattern BMc implemented similarly to a zigzag type. For example, the backside wiring pattern BMc may include first backside wiring patterns extending in the first direction X and second backside wiring patterns extending in the second direction Y, where the first and second backside wiring patterns may be arranged in a zigzag pattern (e.g., the pattern shown in FIG. 15) and may contact each other.

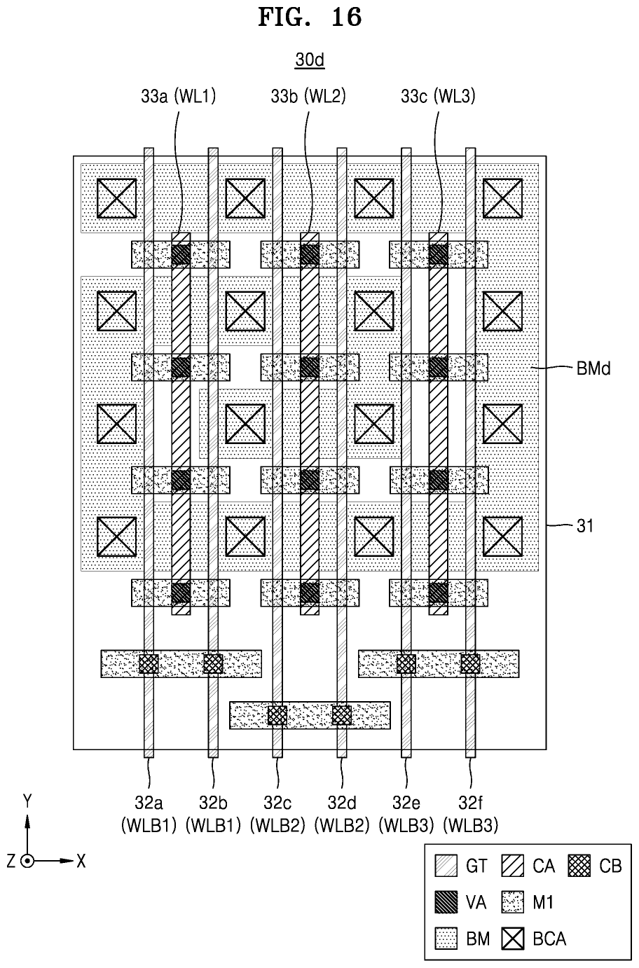

FIG. 16 is a layout of an integrated circuit 30d according to some implementations.

Referring to FIG. 16, the integrated circuit 30d may correspond to a modified example of the integrated circuit 30a of FIG. 13, and the descriptions given above with reference to FIG. 13 may also be applied to this example. The integrated circuit 30d may include a backside wiring pattern BMd implemented similarly to a spiral shape. For example, the backside wiring pattern BMd may include first backside wiring patterns extending in the first direction X and second backside wiring patterns extending in the second direction Y, where the first and second backside wiring patterns may be arranged in a spiral shape (e.g., the pattern shown in FIG. 16) and may contact each other.

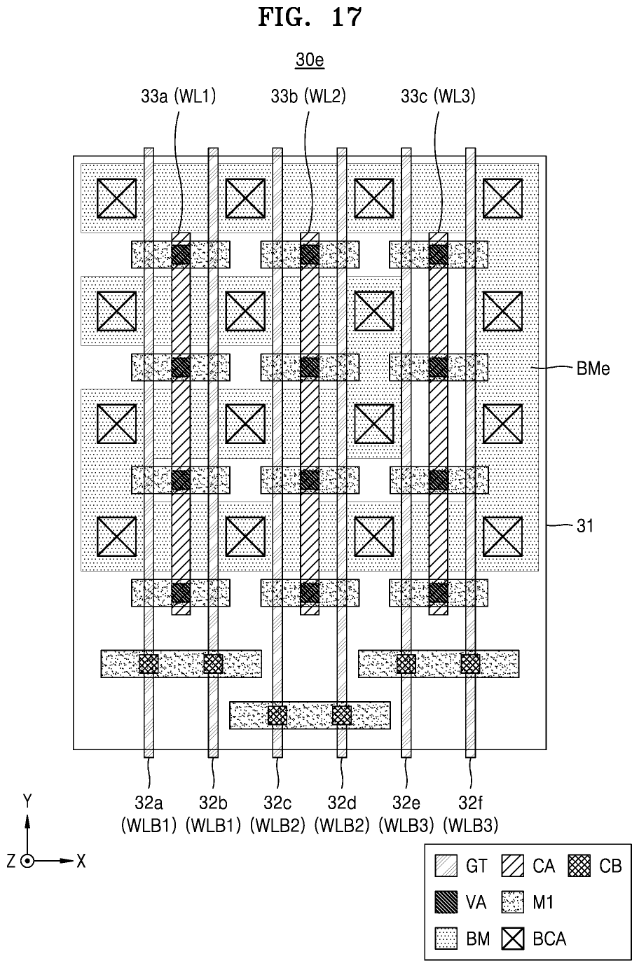

FIG. 17 is a layout of an integrated circuit 30e according to some implementations.

Referring to FIG. 17, the integrated circuit 30e may correspond to a modified example of the integrated circuit 30a of FIG. 13, and the descriptions given above with reference to FIG. 13 may also be applied to this example. The integrated circuit 30e may include a backside wiring pattern BMe. For example, the backside wiring pattern BMe may include first backside wiring patterns extending in the first direction X and second backside wiring patterns extending in the second direction Y, wherein the first and second backside wiring patterns may contact each other.

As described above with reference to FIGS. 13 to 17, an integrated circuit according to some implementations may include (as non-limiting examples) various backside wiring patterns BMa, BMb, BMc, BMd, and BMe that satisfy a design rule of the backside wiring layer BM. As the number of fingers of the multi-finger transistor increases, e.g., as the number of gates of the transistor increases, an area of the backside wiring layer BM may increase. The backside wiring layer BM according to some implementations may be implemented with an area corresponding to the size of the transistor. Compared to the case of placing backside wiring patterns at a constant pitch, power capacitance may be increased and IR drop may be reduced, thereby improving the performance of the integrated circuit.

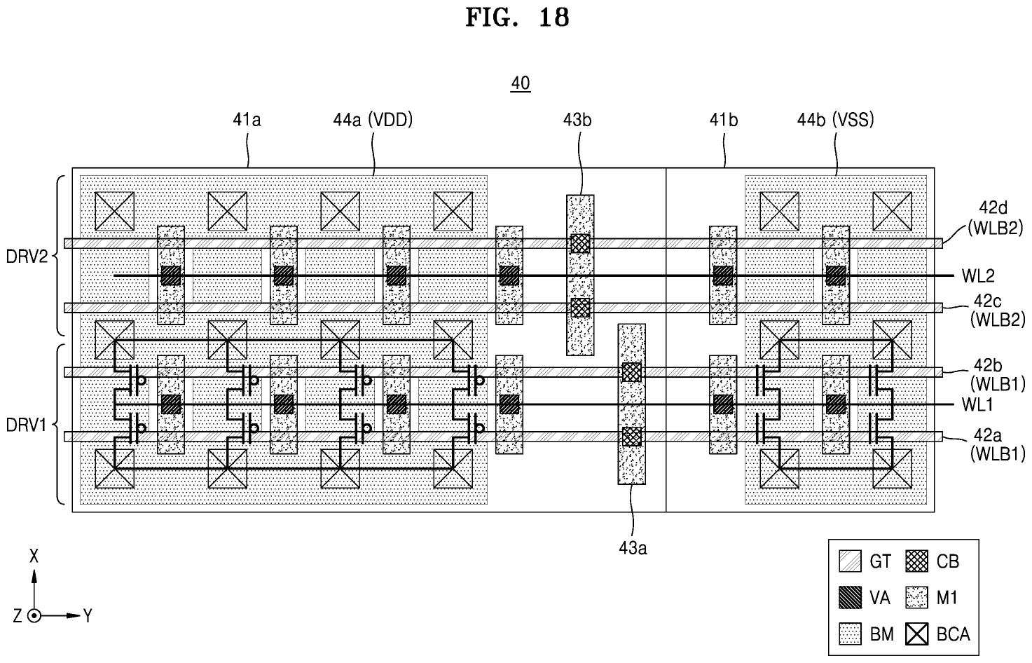

FIG. 18 is a layout of an integrated circuit 40 according to some implementations.

Referring to FIG. 18, the integrated circuit 40 may include gate lines GT, second contacts CB, vias VA, a frontside wiring layer M1, a backside wiring layer BM, and backside contacts BCA. In some implementations, the integrated circuit 40 may correspond to the first and second word line drivers DRV1 and DRV2 of FIG. 9. In some implementations, the integrated circuit 40 may correspond to the first and second word line drivers DRV1 and DRV2 of FIG. 12 or the first and second word line drivers DRV1′ and DRV2′ of FIG. 12. The descriptions given above with reference to FIGS. 1 to 17 may also be applied to this example.

The integrated circuit 40 may include a first active region 41a and a second active region 41b. The first active region 41a may be of a first conductivity type, and, for example, P-type transistors, e.g., PM1 to PM8 of FIG. 10, may be placed in the first active region 41a. The second active region 41b may be of a second conductivity type which is different from the first conductivity type, and, for example, N-type transistors, e.g., NM1 to NM4 of FIG. 10, may be placed in the second active region 41b. In some implementations, the first active region 41a and the second active region 41b may be spaced apart in the second direction Y, and a dummy region may be placed between the first active region 41a and the second active region 41b.

The gate lines GT may include gate lines 42a to 42d each extending in the second direction Y across the first and second active regions 41a and 41b. The second contacts CB may be disposed on the gate lines 42a to 42d, respectively, and each of the gate lines 42a to 42d may receive an input signal, for example, a complementary word line signal, from the frontside wiring layer M1 through the corresponding second contact CB.

The frontside wiring layer M1 may include first and second frontside wiring patterns 43a and 43b that transfer an input signal. The first frontside wiring pattern 43a may receive an input signal for the first word line driver DRV1, for example, the first complementary word line signal WLB1. The first frontside wiring pattern 43a may transfer the first complementary word line signal WLB1 to the gate lines 42a and 42b through the second contacts CB. The second frontside wiring pattern 43b may receive an input signal for the second word line driver DRV2, for example, the second complementary word line signal WLB2. The second frontside wiring pattern 43b may transfer the second complementary word line signal WLB2 to the gate lines 42c and 42d through the second contacts CB.

The backside wiring layer BM may include a first backside wiring pattern 44a disposed on the bottom of the first active region 41a and a second backside wiring pattern 44b disposed on the bottom of the second active region 41b. The first backside wiring pattern 44a may receive a positive supply voltage, for example, the power supply voltage VDD. The first backside wiring pattern 44a may transfer the power supply voltage VDD to the sources of the PMOS transistors PM1 to PM8 of the first word line driver DRV1 through the backside contacts BCA. For example, the first backside wiring pattern 44a may transfer the power supply voltage VDD to the sources of the PMOS transistors PM1 to PM8 of the second word line driver DRV2 through the backside contacts BCA. The second backside wiring pattern 44b may receive a negative supply voltage, for example, the ground voltage VSS. The second backside wiring pattern 44b may transfer the ground voltage VSS to the sources of the NMOS transistors NM1 to NM4 of the first word line driver DRV1 through the backside contacts BCA. In addition, the second backside wiring pattern 44b may transfer the ground voltage VSS to the sources of the NMOS transistors NM1 to NM4 of the second word line driver DRV2 through the backside contacts BCA.

As such, according to some implementations, the backside wiring layer BM may include the first and second backside wiring patterns 44a and 44b that overlap with the first and second word line drivers DRV1 and DRV2 included in the row decoder in the vertical direction Z. The first and second backside wiring patterns 44a and 44b may be connected to source regions of transistors included in the first and second word line drivers DRV1 and DRV2 through the backside contacts BCA. Accordingly, the first backside wiring pattern 44a may provide the power supply voltage VDD to the sources of the PMOS transistors of the first and second word line drivers DRV1 and DRV2 included in the row decoder, and the second backside wiring pattern 44b may provide the negative supply voltage or ground voltage VSS to the sources of the NMOS transistors of the first and second word line drivers DRV1 and DRV2 included in the row decoder.

In some implementations, as the number of word lines connected to the cell array increases, that is, as the number of rows connected to the row decoder increases, the size of the first backside wiring pattern 44a and the second backside wiring pattern 44b may increase. In some implementations, as the number of word line drivers included in the row decoder increases, the size of the first backside wiring pattern 44a and the second backside wiring pattern 44b may increase. In some implementations, as the size of the multi-finger transistor included in the word line driver increases, the size of the first backside wiring pattern 44a and the second backside wiring pattern 44b may increase. As such, according to some implementations, the size of the first and second backside wiring patterns 44a and 44b may be adaptively adjusted according to the size of the word line driver or the size of the multi-finger transistor. Accordingly, the power capacitance may be adaptively adjusted to the word line driver, and the performance of the integrated circuit may be improved by effectively reducing IR drop.

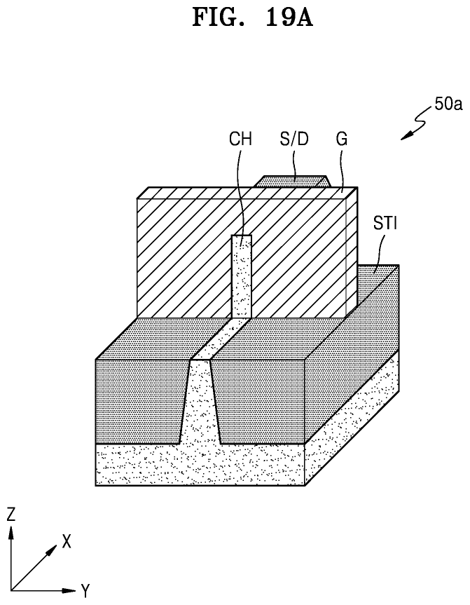

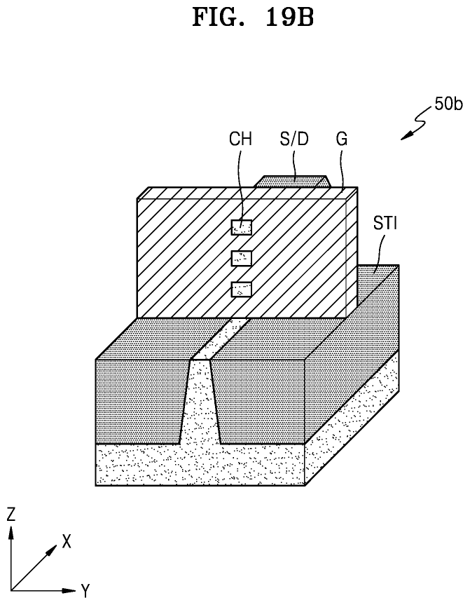

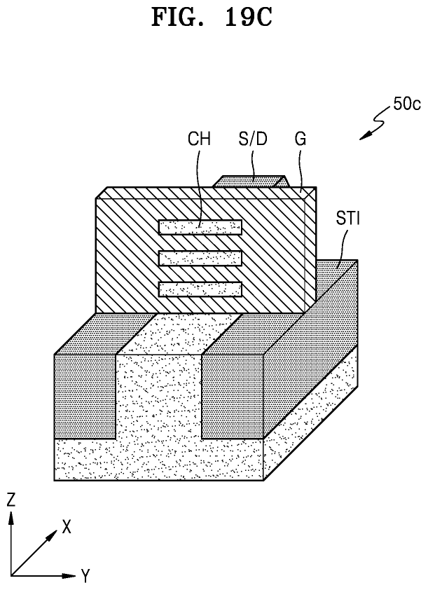

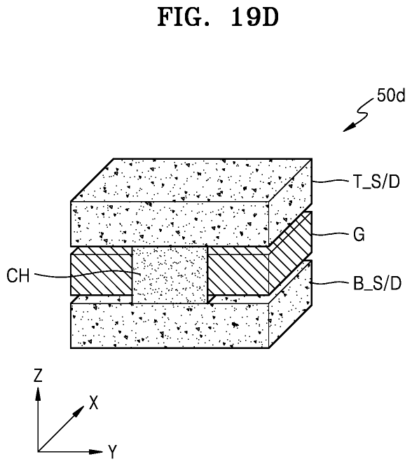

FIGS. 19A to 19D show elements according to some example. For example, FIG. 19A shows a fin type field effect transistor (FinFET) 50a, FIG. 19B shows a gate-all-around field effect transistor (GAAFET) 50b, and FIG. 19C shows a multi-bridge channel field effect transistor (MBCFET) 50c, and FIG. 19D shows a vertical field effect transistor (VFET) 50d. For convenience of illustration, FIGS. 19A to 19C show one of two source/drain regions removed, and FIG. 19D shows a cross-sectional view of the VFET 50d cut through a plane which is parallel to a plane consisting of the second direction Y and the vertical direction Z and passes through a channel CH of the VFET 50d. The transistors shown in FIGS. 19A-19D can be used as transistors in the circuits and structures shown in FIGS. 1-18.

Referring to FIG. 19A, the FinFET 50a may be formed by a fin-shaped active pattern extending in the first direction X between shallow trench isolation structures (STIs) and a gate G extending in the second direction Y. A source/drain S/D may be formed on both sides of the gate G, and accordingly, a source and a drain may be spaced apart from each other in the first direction X. An insulating film may be formed between the channel CH and the gate G. In some implementations, the FinFET 50a may be formed by a plurality of active patterns spaced apart from each other in the second direction Y and the gate G.

Referring to FIG. 19B, the GAAFET 50b may be formed by the active patterns spaced apart from each other in the vertical direction Z and extending in the first direction X, e.g., nanowires, and the gate G extending in the second direction Y. The source/drain S/D may be formed on both sides of the gate G, and accordingly, the source and the drain may be spaced apart from each other in the first direction X. An insulating film may be formed between the channel CH and the gate G. The number of nanowires included in the GAAFET 50b is not limited to that shown in FIG. 19B.

Referring to FIG. 19C, the MBCFET 50c may be formed by the active patterns spaced apart from each other in the vertical direction Z and extending in the first direction X, i.e., nanosheets, and the gate G extending in the second direction Y. The source/drain S/D may be formed on both sides of the gate G, and accordingly, the source and the drain may be spaced apart from each other in the first direction X. An insulating film may be formed between the channel CH and the gate G. The number of nanosheets included in the MBCFET 50c is not limited to that shown in FIG. 19C.

Referring to FIG. 19D, the VFET 50d may include a top source/drain T_S/D and a bottom source/drain B_S/D which are spaced apart from each other in the vertical direction Z with the channel CH in between. The VFET 50d may include the gate G surrounding the circumference of the channel CH between the top source/drain T_S/D and the bottom source/drain B_S/D. An insulating film may be formed between the channel CH and the gate G.

However, the transistor according to some implementations is not limited to the above-described structure. For example, the integrated circuit may include a ForkFET having a structure in which the N-type transistor and the P-type transistor are closer together as the nanosheets for the P-type transistor and the nanosheets for the N-type transistor are separated by a dielectric wall. As another example, the integrated circuit may include a bipolar junction transistor as well as FET such as a complementary field effect transistor (CFET), negative capacitance field effect transistor (NCFET), carbon nanotube field effect transistor (CNT FET), and/or the like.

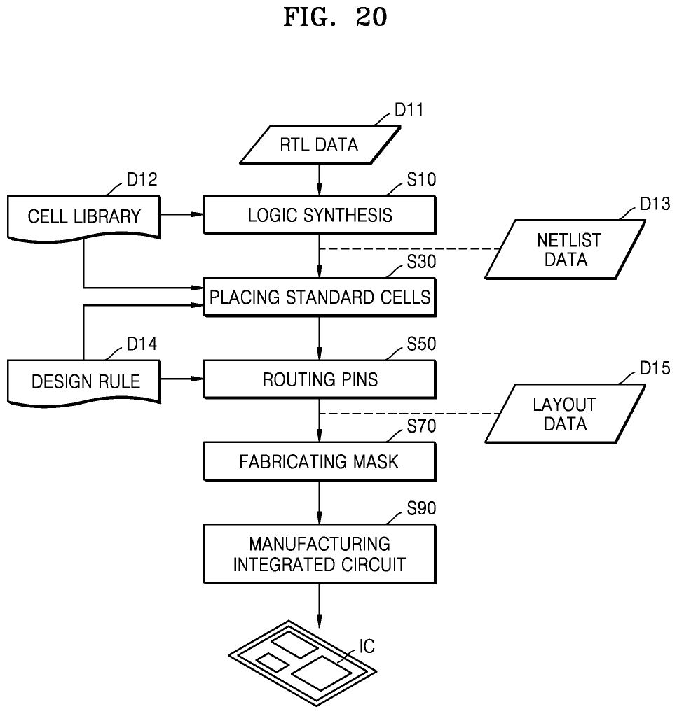

FIG. 20 is a flowchart of a method of manufacturing an integrated circuit according to some implementations, for example, any of the integrated circuits discussed with respect to FIGS. 1-19.

Referring to FIG. 20, the method according to some implementations is a method of manufacturing an integrated circuit IC including standard cells, and may include a plurality of stages S10, S30, S50, S70, and S90. A cell library (or standard cell library) D12 may include information about standard cells, such as information about functions, characteristics, layouts, etc. In some implementations, the cell library D12 may define tap cells and dummy cells as well as functional cells that generate output signals from input signals. In some implementations, the cell library D12 may define memory cells and dummy cells having the same footprint. A design rule D14 may include requirements that a layout of an integrated circuit IC must comply with. For example, the design rule D14 may include requirements for a distance (space) between patterns in the same layer, a minimum width of the patterns, a routing direction of the wiring layer, and the like. In some implementations, the design rule D14 may define a minimum separation distance within the same track of the wiring layer.

In stage S10, a logical synthesis operation may be performed to generate netlist data D13 from register-transfer level (RTL) data D11. For example, a semiconductor design tool (e.g., a logic synthesis tool) may perform logic synthesis by referencing the cell library D12 from the RTL data D11 written in a hardware description language (HDL) such as VHSIC hardware description language (VHDL) and Verilog, and may generated the netlist data D13 including bitstream or netlist. The netlist data D13 may correspond to input of place and routing, which is described below.

In stage S30, standard cells may be placed. For example, the semiconductor design tool (e.g., Place & Route (P & R) tool) may place the standard cells used in the netlist data D13 with reference to the cell library D12. In some implementations, the semiconductor design tool may place the standard cells in rows extending in the X-axis or Y-axis direction, and the placed standard cells may receive power from a power rail extending along the row boundaries.

In stage S50, pins of the standard cells may be routed. For example, the semiconductor design tool may create interconnections that electrically connect output pins and input pins of the placed standard cells, and may generate the layout data D15 that defines the placed standard cells and the created interconnections. The interconnections may include patterns of wiring layers and/or vias of via layers. The wiring layers may include a frontside wiring layer disposed on the top of the front side of the substrate and a backside wiring layer disposed on the back side of the substrate. The layout data D15 may have a format such as GDSII, and may include geometric information of cells and interconnections. The semiconductor design tool may refer to the design rule D14 while routing the pins of the cells. The layout data D15 may correspond to the output of place and routing. Stage S50 alone, or stages S30 and S50 collectively, may be referred to as a method for designing an integrated circuit.

In some implementations, as illustrated in FIGS. 1 to 18, the integrated circuit may include the backside wiring layer that overlaps with the word line driver in the vertical direction, and the transistors included in the word line driver may be connected to the backside wiring layer through backside contacts. For example, a source of each transistor included in the word line driver may be connected to the backside wiring layer through the backside contact, and may receive power such as a power supply voltage or ground voltage from the backside wiring layer through the backside contact. Accordingly, the resistance of the power wiring connected to the word line driver may be reduced, and thus, IR drop may be reduced, thereby improving the performance of the integrated circuit. Additionally, the routing freedom of the frontside wiring layer may be improved.

In stage S70, the operation of fabricating a mask may be performed. For example, in photolithography, optical proximity correction (OPC) to correct distortion such as refraction due to the characteristics of light may be applied to the layout data D15. Patterns on a mask may be defined to form patterns arranged in a plurality of layers based on OPC-applied data, and at least one mask (or photomask) may be fabricated to form patterns in each of the plurality of layers. In some implementations, the layout of the integrated circuit IC may be limitedly modified in stage S70, and the limited modification of the integrated circuit IC in stage S70 as a post-processing for optimizing the structure of the integrated circuit IC, may be referred to as design polishing.

In stage S90, an operation of manufacturing the integrated circuit IC may be performed. For example, the integrated circuit IC may be manufactured by patterning the plurality of layers using at least one mask fabricated in stage S70. A front-end-of-line (FEOL) may include, for example, planarizing and cleaning a wafer, forming a trench, forming a well, forming a gate line, and forming a source and a drain. By the FEOL, individual elements such as transistors, capacitors, resistors, and the like may be formed on the substrate. Additionally, a back-end-of-line (BEOL) may include, for example, siliciding the gate, source, and drain regions, adding a dielectric, planarizing the dielectric, forming a hole, adding a metal layer, forming a via, forming a passivation layer, etc. By the BEOL, individual elements such as transistors, capacitors, resistors, and the like may be interconnected. In some implementations, a middle-of-line (MOL) may be performed between the FEOL and the BEOL, and contacts may be formed on the individual elements. The integrated circuit IC may then be packaged in a semiconductor package and used as a component in a variety of applications.

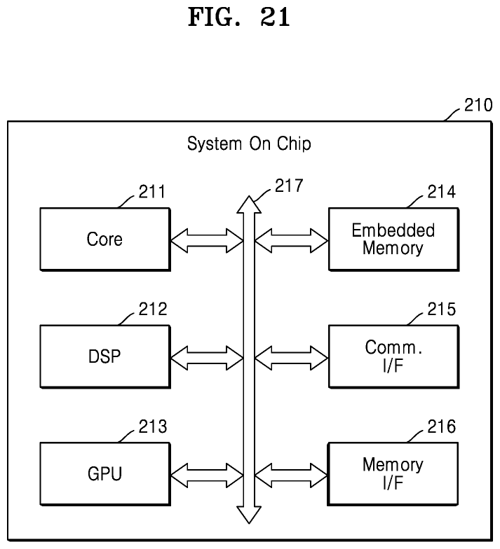

FIG. 21 is a block diagram of a system-on-chip 210 according to some implementations.

Referring to FIG. 21, the system on chip SoC 210 may refer to an integrated circuit that integrates components of a computing system or other electronic system. For example, an application processor AP as an example of the SoC 210 may include a processor and components for other functions. The SoC 210 may include a core 211, a digital signal processor (DSP) 212, a graphics processing unit (GPU) 213, a built-in memory 214, a communication interface 215, and a memory interface 216. The components of the SoC 210 may communicate with each other through a bus 217.

The core 211 may process instructions and control the operation of the components included in the SoC 210. For example, the core 211 may drive an operating system and run applications on the operating system by processing a series of instructions. The DSP 212 may generate useful data by processing digital signals, for example, digital signals provided from the communication interface 215. The GPU 213 may generate data for an image output through a display device from image data provided from the built-in memory 214 or the memory interface 216, and may encode the image data. In some implementations, the integrated circuits described above with reference to FIGS. 1-19 may be included in the core 211, the DSP 212, the GPU 213, and/or the built-in memory 214.

The built-in memory 214 may store data necessary for the core 211, the DSP 212, and the GPU 213 to operate. The communication interface 215 may provide an interface for communication network or one-to-one communication. The memory interface 216 may provide an interface to external memory of the SoC 210, such as DRAM and flash memory.

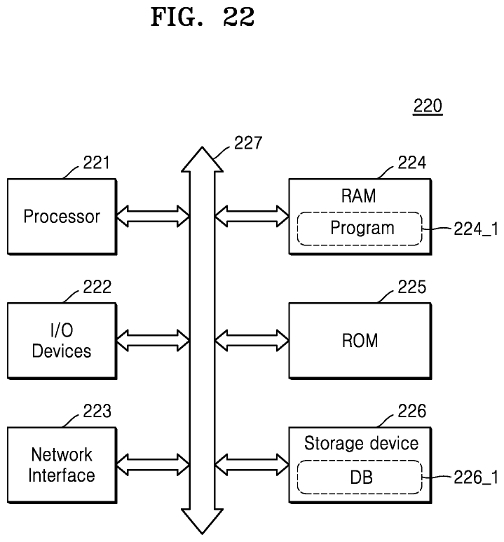

FIG. 22 is a block diagram of a computing system 220 including memory for storing a program according to some implementations.

Referring to FIG. 22, according to some implementations, a method of designing an integrated circuit, e.g., at least some of the stages in the above-described flowchart may be performed on a computing system (or computer) 220. The computing system 220 may include a processor 221, I/O devices 222, a network interface 223, random access memory (RAM) 224, read only memory (ROM) 225, and a storage device 226. The processor 221, the I/O devices 222, the network interface 223, the RAM 224, the ROM 225, and the storage device 226 may be connected to the bus 227 and communicate with each other through the bus 227.

The processor 221 may be referred to as a processing unit, and may include at least one core capable of executing any instruction set (e.g., Intel Architecture-32 (IA-32), 64-bit extended IA-32, x86-64, PowerPC, Sparc, MIPS, ARM, IA-64, etc.), like microprocessor, application processor (AP), digital signal processor (DSP), and graphic processing unit (GPU). For example, the processor 221 may access memory, that is, the RAM 224 or the ROM 225, through the bus 227, and may execute instructions stored in the RAM 224 or the ROM 225.

The RAM 224 may store a program 224_1 or at least a portion thereof for a method of designing an integrated circuit according to some implementations, and the program 224_1 may cause the processor 221 to perform at least some of the stages included in the method of designing an integrated circuit, for example, the method of FIG. 20. That is, the program 224_1 may include a plurality of instructions executable by the processor 221, and the plurality of instructions included in the program 224_1 may cause the processor 221 to perform, for example, at least some of the stages included in the above-described flowchart.

The storage device 226 may not lose stored data even when power supplied to the computing system 220 is cut off. The storage device 226 may store the program 224_1 according to some implementations, and the program 224_1 or at least a portion thereof may be loaded into the RAM 224 from the storage device 226 before the program 224_1 is executed by the processor 221. Alternatively, the storage device 226 may store a file written in a program language, and the program 224_1 or at least a portion thereof generated by a compiler or the like from the file may be loaded into the RAM 224. Additionally, the storage device 226 may store a database 226_1, and may include information necessary for designing an integrated circuit, such as information on designed blocks, the cell library D12 and/or the design rule D14 of FIG. 20.

The storage device 226 may store data to be processed by the processor 221 or data processed by the processor 221. That is, the processor 221 may generate data by processing data stored in the storage device 226 according to the program 224_1, and may store the generated data in the storage device 226. For example, the storage device 226 may store the RTL data D11, the netlist data D13, and/or the layout data D15 of FIG. 20.

The I/O devices 222 may include an input device such as a keyboard, a pointing device, etc., and may include an output device such as a display device, a printer, etc. For example, a user may trigger execution of the program 224_1 by the processor 221 through the I/O devices 222, may input the RTL data D11 and/or the netlist data D13 of FIG. 20, and may check the layout data D15 of FIG. 20. The network interface 223 may provide access to a network external to the computing system 220. For example, the network may include multiple computing systems and communication links, wherein the communication links may include wired links, optical links, wireless links, or any other type of links.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

While implementations according to the present disclosure have been particularly shown and described with reference to examples thereof, it will be understood that various changes in form and details may be made therein without departing from the spirit and scope of the following claims.

What is claimed is:

1. An integrated circuit comprising:
a cell array disposed on a substrate and including a plurality of bit cells;
a row decoder including a plurality of word line drivers, each word liner driver configured to provide a word line signal to the cell array;
a backside wiring layer disposed on a back side of the substrate at least partially under the row decoder and configured to provide power to the plurality of word line drivers; and
a plurality of backside contacts between the row decoder and the backside wiring layer,
wherein each of the plurality of backside contacts extends from a source of at least one transistor included in the plurality of word line drivers to the backside wiring layer.

2. The integrated circuit of claim 1, further comprising a frontside wiring layer disposed above a front side of the substrate in a vertical direction and including a plurality of frontside wiring patterns configured to receive word line signals from the plurality of word line drivers.

3. The integrated circuit of claim 1,
wherein each of the plurality of word line drivers comprises at least one P-type transistor and at least one N-type transistor, and
wherein the backside wiring layer comprises at least one of:
a first backside wiring pattern configured to provide a positive supply voltage to the plurality of word line drivers, or
a second backside wiring pattern configured to provide a negative supply voltage to the plurality of word line drivers.

4. The integrated circuit of claim 3,
wherein the positive supply voltage comprises a power supply voltage, and the negative supply voltage comprises a ground voltage.

5. The integrated circuit of claim 3, wherein the plurality of backside contacts comprise at least one of:
a first backside contact disposed on the first backside wiring pattern and configured to transfer the positive supply voltage to the at least one P-type transistor, or
a second backside contact disposed on the second backside wiring pattern and configured to transfer the negative supply voltage to the at least one N-type transistor.

6. The integrated circuit of claim 3,
wherein at least one of the first backside wiring pattern or the second backside wiring pattern has a wide area configuration corresponding to an area over which of a plurality of transistors of a first word line driver of the plurality of word line drivers are disposed.

7. The integrated circuit of claim 6, wherein the backside wiring layer comprises at least one of:
the first backside wiring pattern, wherein the first backside wiring pattern comprises a first continuous metal layer extending on the back side of the substrate under a plurality of P-type transistors of the first word line driver of the plurality of word line drivers, or
the second backside wiring pattern, wherein the second backside wiring pattern comprises a second continuous metal layer extending on the back side of the substrate under a plurality of N-type transistors of the first word line driver of the plurality of word line drivers.

8. The integrated circuit of claim 1,
wherein the backside wiring layer comprises a mesh-type wiring pattern.

9. The integrated circuit of claim 1,
wherein the backside wiring layer comprises a first backside wiring pattern extending in a first direction; and
a second backside wiring pattern extending in a second direction perpendicular to the first direction and contacting the first backside wiring pattern.

10. An integrated circuit comprising:
a cell array disposed on a substrate and including a plurality of bit cells;
a plurality of word line drivers, each word line driver providing a word line signal to the cell array;
a frontside wiring layer disposed above a front side of the substrate in a vertical direction and including a plurality of frontside wiring patterns configured to receive word line signals from the plurality of word line drivers; and
a backside wiring layer disposed on a back side of the substrate at least partially under the plurality of word line drivers and configured to provide power to the plurality of word line drivers,
wherein each of the plurality of word line drivers comprises a plurality of transistors, and
wherein each of the plurality of transistors comprises a source connected to the backside wiring layer.

11. The integrated circuit of claim 10, further comprising
a plurality of backside contacts between the plurality of word line drivers and the backside wiring layer,
wherein the plurality of backside contacts each extend from sources of the plurality of transistors to the backside wiring layer.

12. The integrated circuit of claim 11,
wherein each of the plurality of word line drivers comprises at least one P-type transistor and at least one N-type transistor, and
wherein the backside wiring layer comprises at least one of:
a first backside wiring pattern configured to provide a positive supply voltage to the plurality of word line drivers, or
a second backside wiring pattern configured to provide a negative supply voltage to the plurality of word line drivers.

13. The integrated circuit of claim 12,
wherein the positive supply voltage comprise a power supply voltage, and the negative supply voltage comprises a ground voltage.

14. The integrated circuit of claim 12, wherein the plurality of backside contacts comprise at least one of:
a first backside contact disposed on the first backside wiring pattern and configured to transfer the positive supply voltage to the at least one P-type transistor, or
a second backside contact disposed on the second backside wiring pattern and configured to transfer the negative supply voltage to the at least one N-type transistor.

15. The integrated circuit of claim 12, wherein at least one of the first backside wiring pattern or the second backside wiring pattern has a wide area configuration corresponding to an area over which of a plurality of transistors of a first word line driver of the plurality of word line drivers are disposed.

16. The integrated circuit of claim 15, wherein the backside wiring layer comprises at least one of:
the first backside wiring pattern, wherein the first backside wiring pattern comprises a first continuous metal layer extending on the back side of the substrate under a plurality of P-type transistors of the first word line driver of the plurality of word line drivers, or
the second backside wiring pattern, wherein the second backside wiring pattern comprises a second continuous metal layer extending on the back side of the substrate under a plurality of N-type transistors of the first word line driver of the plurality of word line drivers.

17. An integrated circuit comprising:
a cell array including a plurality of bit cells;
a plurality of word line drivers, each word line driver providing a word line signal to the cell array;
a frontside wiring layer disposed above the plurality of word line drivers in a vertical direction and including a plurality of frontside wiring patterns configured to receive word line signals from the plurality of word line drivers;
a backside wiring layer disposed under the plurality of word line drivers in the vertical direction and including a first backside wiring pattern configured to provide a power supply voltage to the plurality of word line drivers and a second backside wiring pattern configured to provide a ground voltage to the plurality of word line drivers;
a plurality of first backside contacts between the plurality of word line drivers and the first backside wiring pattern; and
a plurality of second backside contacts between the plurality of word line drivers and the second backside wiring pattern.

18. The integrated circuit of claim 17,
wherein each of the plurality of word line drivers comprises at least one P-type transistor and at least one N-type transistor,
wherein the first backside wiring pattern is configured to provide the power supply voltage to a source of the at least one P-type transistor, and
wherein the second backside wiring pattern is configured to provide the ground voltage to a source of the at least one N-type transistor.

19. The integrated circuit of claim 18, wherein at least one of the first backside wiring pattern or the second backside wiring pattern has a wide area configuration corresponding to an area over which of a plurality of transistors of a first word line driver of the plurality of word line drivers are disposed.

20. The integrated circuit of claim 19, wherein the backside wiring layer comprises at least one of:
the first backside wiring pattern, wherein the first backside wiring pattern comprises a first continuous metal layer extending on the back side of the substrate under a plurality of P-type transistors of the first word line driver of the plurality of word line drivers, or
the second backside wiring pattern, wherein the second backside wiring pattern comprises a second continuous metal layer extending on the back side of the substrate under a plurality of N-type transistors of the first word line driver of the plurality of word line drivers.
